(19) United States
(12) Patent Application Publication
(10) Pub. No.: US 2026/0244116 A1
(43) Pub. Date: Aug. 20, 2026

(54) SUBSTRATE SUPPORT AND LITHOGRAPHIC APPARATUS

(71) Applicant: ASML NETHERLANDS B.V., Veldhoven (NL)

(72) Inventor: Niek Jacobus Johannes ROSET

(73) Assignee: ASML NETHERLANDS B.V., Veldhoven (NL)

(21) Appl. No.: 18/872,151

(22) PCT Filed: May 24, 2023
(86) PCT No.: PCT/EP2023/063903

§ 371 Date: Dec. 5, 2024

(30) Foreign Application Priority Data
Jun. 15, 2022 (EU) 22179329.2

(51) Int. Cl. G03F 7/00; H10P 72/76

(52) U.S. Cl. CPC G03F 7/70716; G03F 7/70866; G03F 7/7095; H10P 72/7614; H10P 72/7624

(57) ABSTRACT

A substrate support configured to support a substrate in a lithographic apparatus, the support including: a first circumferential wall; a first opening radially outwards of the first circumferential wall and configured to supply and/or extract gas; a second circumferential wall radially outwards of the first opening; a second opening in fluid communication with ambient pressure and radially outwards of the second circumferential wall; a third circumferential wall radially outwards of the second opening; a third opening radially outwards of the third circumferential wall and configured to extract fluid; and a fourth circumferential wall radially outwards of the third opening.

### CROSS-REFERENCE TO RELATED APPLICATIONS

This application claims priority of EP application 22179329.2 which was filed on Jun. 15, 2022 and which is incorporated herein in its entirety by reference.

### FIELD

The present invention relates to a substrate support configured to support a substrate in a lithographic apparatus, a method of loading a substrate onto a substrate support, a lithographic apparatus including a substrate support, and a method of manufacturing a device including a method of loading a substrate onto a substrate support.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer). Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction.

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Further improvements in the resolution of smaller features may be achieved by providing an immersion fluid having a relatively high refractive index, such as water, on the substrate during exposure. The effect of the immersion fluid is to enable imaging of smaller features since the exposure radiation will have a shorter wavelength in the fluid than in gas. The effect of the immersion fluid may also be regarded as increasing the effective numerical aperture (NA) of the system and also increasing the depth of focus.

The immersion fluid may be confined to a localized area between the projection system of the lithographic apparatus and the substrate by a fluid handling structure.

### SUMMARY

In a semiconductor manufacturing process, a substrate is supported on a substrate support. Specifically, the substrate is supported on a plurality of burls protruding from the a surface of the substrate support.

In the semiconductor industry, there is an increasing trend towards integrating more functionality onto unit surfaces of substrates by shrinking, and increasing the number of, stacked film layers on the substrate. Increasing the number of layers stacked on a substrate increases the stress induced between the film and the substrate, which can cause significant substrate warpage.

This can cause variable friction between the outer circumferential ring of burls and the underside of the substrate, which leads to high substrate reproducibility. This can be mitigated by surrounding the outer circumferential ring of burls with fluid, i.e., immersion fluid. However, this results in a higher humidity gradient, which causes a drift in the flatness of the substrate support.

It is an object of the present invention to mitigate the problems associated with the loading of a warped substrate, without increasing the flatness drift of the substrate support.

According to the present invention, there is provided a substrate support configured to support a substrate in a lithographic apparatus, comprising:
a first circumferential wall;
a first opening radially outwards of the first circumferential wall and configured to supply and/or extract gas;
a second circumferential wall radially outwards of the first opening;
a second opening in fluid communication with ambient pressure and radially outwards of the second circumferential wall;
a third circumferential wall radially outwards of the second opening;
a third opening radially outwards of the third circumferential wall and configured to extract fluid; and
a fourth circumferential wall radially outwards of the third opening.

According to the present invention, there is also provided a method of loading a substrate onto a substrate support having a first circumferential wall, a second circumferential wall radially outward of the first circumferential wall, a third circumferential wall radially outward of the second circumferential wall, and a fourth circumferential wall radially outward of the third circumferential wall, with a first region between the first circumferential wall and the second circumferential wall, a second region between the second circumferential wall and the third circumferential wall, and a third region between the third and fourth circumferential wall, the method comprising:
a substrate loading step, wherein gas is supplied to the first region;
a substrate clamp step, wherein the gas is extracted from the first region, and fluid is extracted from the third region.

According to the present invention, there is also provided a lithographic apparatus including a substrate support.

According to the present invention, there is also provided a method of manufacturing a device including a method of loading a substrate onto a substrate support.

Further embodiments, features and advantages of the present invention, as well as the structure and operation of the various embodiments, features and advantages of the present invention are described in detail below with reference to the accompanying drawings.

### DESCRIPTION OF THE DRAWINGS

Embodiments of the invention will now be described, by way of example only, with reference to the accompanying schematic drawings, in which corresponding reference symbols indicate corresponding parts, and in which:

FIG. 1 depicts a schematic overview of the lithographic apparatus;

FIGS. 2 and 3 depict, in cross-section, two different versions of a fluid handling system for use in a lithographic projection apparatus;

FIG. 4 depicts, in cross-section, a substrate support not in accordance with the present invention.

FIG. 5 depicts, in cross-section, a portion of a substrate support not in accordance with the present invention (a comparative example), in a loading state.

FIG. 6 depicts, in cross-section, a portion of a substrate support not in accordance with the present invention (a comparative example), in a clamp state.

FIG. 7 depicts, in cross-section, a portion of a substrate support in accordance with the present invention, in a loading state.

FIG. 8 depicts, in cross-section, a portion of a substrate support in accordance with the present invention, in a clamp state.

FIG. 9 depicts, in cross-section, a portion of a substrate support in accordance with the present invention, in a bypass state.

FIG. 10 depicts, in cross-section, a portion of a substrate support in accordance with the present invention, in a clamp state.

FIG. 11A depicts a multi-functional channel and multi-functional passageways that may be included in a substrate support in accordance with the present invention.

FIG. 11B depicts multi-functional channels and multi-functional passageways that may be included in a substrate support in accordance with the present invention.

FIG. 12 depicts a plot of the moment about a horizontal axis (M) against tilt angle (θ) for a single multi-functional channel and three multi-functional channels at several flow rates.

The features shown in the Figures are not necessarily to scale, and the size and/or arrangement depicted is not limiting. It will be understood that the Figures include optional features which may not be essential to the invention. Furthermore, not all of the features of the apparatus are depicted in each of the figures, and the Figures may only show some of the components relevant for describing a particular feature.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

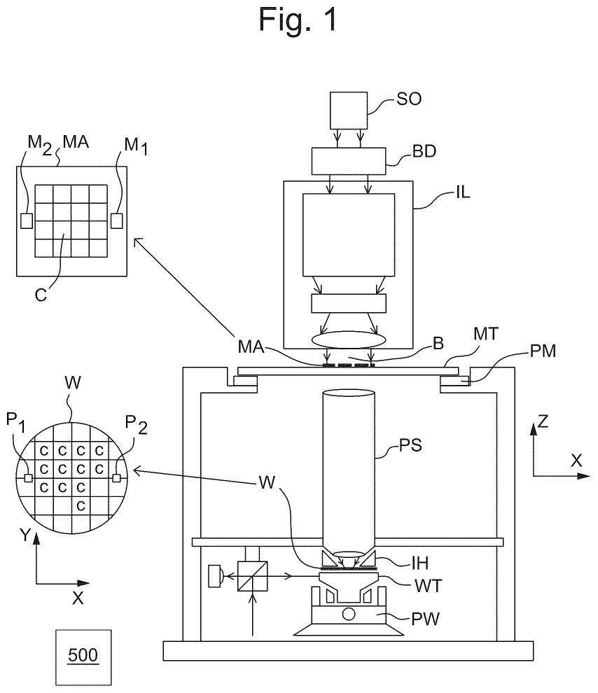

FIG. 1 schematically depicts a lithographic apparatus. The lithographic apparatus includes an illumination system (also referred to as illuminator) IL configured to condition a radiation beam B (e.g., UV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross-section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus is of a type wherein at least a portion of the substrate W may be covered by an immersion liquid having a relatively high refractive index, e.g., water, so as to fill an immersion space 11 between the projection system PS and the substrate W—which is also referred to as immersion lithography. More information on immersion techniques is given in U.S. Pat. No. 6,952,253, which is incorporated herein by reference.

The lithographic apparatus may be of a type having two or more substrate supports WT (also named “dual stage”). In such a “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in figures). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Immersion techniques have been introduced into lithographic systems to enable improved resolution of smaller features. In an immersion lithographic apparatus, a liquid layer of immersion liquid having a relatively high refractive index is interposed in the immersion space 11 between a projection system PS of the apparatus (through which the patterned beam is projected towards the substrate W) and the substrate W. The immersion liquid covers at least the part of the substrate W under a final element of the projection system PS. Thus, at least the portion of the substrate W undergoing exposure is immersed in the immersion liquid.

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space 11 as immersion liquid. Other liquids with a high refractive index can be used besides water as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the immersion space 11 between the final element and a surface facing the final element. The facing surface is a surface of substrate W or a surface of the supporting stage (or substrate support WT) that is co-planar with the surface of the substrate W. (Please note that reference in the following text to surface of the substrate W also refers in addition or in the alternative to the surface of the substrate support WT, unless expressly stated otherwise; and vice versa). A fluid handling structure IH present between the projection system PS and the substrate support WT is used to confine the immersion liquid to the immersion space 11. The immersion space 11 filled by the immersion liquid is smaller in plan than the top surface of the substrate W and the immersion space 11 remains substantially stationary relative to the projection system PS while the substrate W and substrate support WT move underneath.

Other immersion systems have been envisaged such as an unconfined immersion system (a so-called ’All Wet’ immersion system) and a bath immersion system. In an unconfined immersion system, the immersion liquid covers more than the surface under the final element. The liquid outside the immersion space 11 is present as a thin liquid film. The liquid may cover the whole surface of the substrate W or even the substrate W and the substrate support WT co-planar with the substrate W. In a bath type system, the substrate W is fully immersed in a bath of immersion liquid.

The fluid handling structure IH is a structure which supplies the immersion liquid to the immersion space 11, removes the immersion liquid from the immersion space 11 and thereby confines the immersion liquid to the immersion space 11. It includes features which are a part of a fluid supply system. The arrangement disclosed in PCT patent application publication no. WO 99/49504 is an early fluid handling structure comprising pipes which either supply or recover the immersion liquid from the immersion space 11 and which operate depending on the relative motion of the stage beneath the projection system PS. In more recent designs, the fluid handling structure extends along at least a part of a boundary of the immersion space 11 between the final element of the projection system PS and the substrate support WT or substrate W, so as to in part define the immersion space 11.

The fluid handing structure IH may have a selection of different functions. Each function may be derived from a corresponding feature that enables the fluid handling structure IH to achieve that function. The fluid handling structure IH may be referred to by a number of different terms, each referring to a function, such as barrier member, seal member, fluid supply system, fluid removal system, liquid confinement structure, etc.

As a barrier member, the fluid handling structure IH is a barrier to the flow of the immersion liquid from the immersion space 11. As a liquid confinement structure, the structure confines the immersion liquid to the immersion space 11. As a seal member, sealing features of the fluid handling structure IH form a seal to confine the immersion liquid to the immersion space 11. The sealing features may include an additional gas flow from an opening in the surface of the seal member, such as a gas knife.

The fluid handling structure IH may supply immersion fluid and therefore be a fluid supply system.

The fluid handling structure IH may at least partly confine immersion fluid and thereby be a fluid confinement system.

The fluid handling structure IH may provide a barrier to immersion fluid and thereby be a barrier member, such as a fluid confinement structure.

The fluid handling structure IH may create or use a flow of gas, for example to help in controlling the flow and/or the position of the immersion fluid.

The flow of gas may form a seal to confine the immersion fluid so the fluid handling structure IH may be referred to as a seal member; such a seal member may be a fluid confinement structure.

Immersion liquid may be used as the immersion fluid. In that case the fluid handling structure IH may be a liquid handling system. In reference to the aforementioned description, reference in this paragraph to a feature defined with respect to fluid may be understood to include a feature defined with respect to liquid.

A lithographic apparatus has a projection system PS. During exposure of a substrate W, the projection system PS projects a beam of patterned radiation onto the substrate W. To reach the substrate W, the path of the radiation beam B passes from the projection system PS through the immersion liquid confined by the fluid handling structure IH between the projection system PS and the substrate W. The projection system PS has a lens element, the last in the path of the beam, which is in contact with the immersion liquid. This lens element which is in contact with the immersion liquid may be referred to as ‘the last lens element’ or “the final element”. The final element is at least partly surrounded by the fluid handling structure IH. The fluid handling structure IH may confine the immersion liquid under the final element and above the facing surface.

As depicted in FIG. 1, the lithographic apparatus comprises a controller 500. The controller 500 is configured to control the substrate table WT.

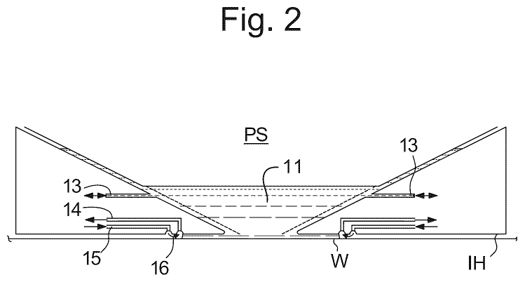

FIG. 2 schematically depicts a localized liquid supply system or fluid handling system. The liquid supply system is provided with a fluid handling structure IH (or liquid confinement structure), which extends along at least a part of a boundary of the space 11 between the final element of the projection system PS and the support table WT or substrate W. The fluid handling structure IH is substantially stationary relative to the projection system PS in the XY plane though there may be some relative movement in the Z direction (in the direction of the optical axis). In an example, a seal is formed between the fluid handling structure IH and the surface of the substrate W and may be a contactless seal such as a gas seal (such a system with a gas seal is disclosed in EP1,420,298) or liquid seal.

The fluid handling structure IH at least partly confines the immersion liquid in the space 11 between the final element of the projection system PS and the substrate W. The space 11 is at least partly formed by the fluid handling structure IH positioned below and surrounding the final element of the projection system PS. Immersion liquid is brought into the space 11 below the projection system PS and within the fluid handling structure IH by one of liquid openings 13. The immersion liquid may be removed by another of liquid openings 13. The immersion liquid may be brought into the space 11 through at least two liquid openings 13. Which of liquid openings 13 is used to supply the immersion liquid and optionally which is used to remove the immersion liquid may depend on the direction of motion of the support table WT.

The immersion liquid may be confined in the space 11 by a contactless seal such as a gas seal 16 formed by a gas which, during use, is formed between the bottom of the fluid handling structure IH and the surface of the substrate W. The gas in the gas seal 16 is provided under pressure via inlet 15 to the gap between the fluid handling structure IH and substrate W. The gas is extracted via outlet 14. The overpressure on the gas inlet 15, vacuum level on the outlet 14 and geometry of the gap are arranged so that there is a high-velocity gas flow inwardly that confines the immersion liquid. Such a system is disclosed in US 2004/0207824, which is hereby incorporated by reference in its entirety. In an example, the fluid handling structure IH does not have the gas seal 16.

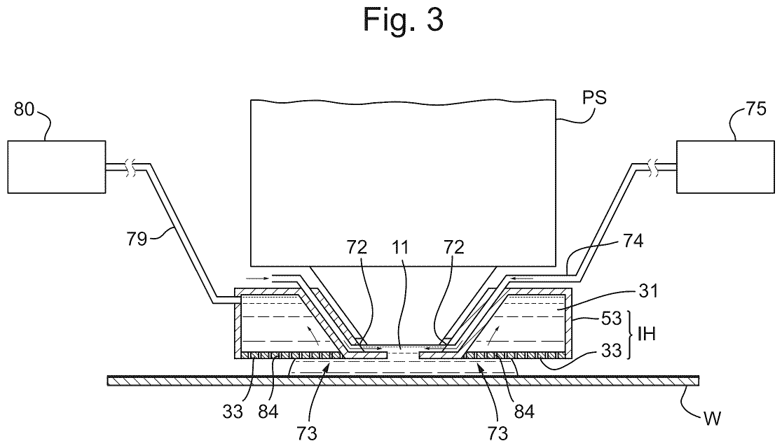

FIG. 3 is a side cross-sectional view that depicts a further liquid supply system or fluid handling system. The arrangement illustrated in FIG. 3 and described below may be applied to the lithographic apparatus described above and illustrated in FIG. 1. The liquid supply system is provided with a fluid handling structure IH (or a liquid confinement structure), which extends along at least a part of a boundary of the space 11 between the final element of the projection system PS and the support table WT or substrate W.

The fluid handling structure IH at least partly confines the immersion liquid in the space 11 between the final element of the projection system PS and the substrate W. The space 11 is at least partly formed by the fluid handling structure IH positioned below and surrounding the final element of the projection system PS. In an example, the fluid handling structure IH comprises a main body member 53 and a porous member 33. The porous member 33 is plate shaped and has a plurality of holes (i.e., openings or pores). The porous member 33 may be a mesh plate wherein numerous small holes 84 are formed in a mesh. Such a system is disclosed in US 2010/0045949 A1, which is hereby incorporated by reference in its entirety.

The main body member 53 comprises supply ports 72, which are capable of supplying the immersion liquid to the space 11, and a recovery port 73, which is capable of recovering the immersion liquid from the space 11. The supply ports 72 are connected to a liquid supply apparatus 75 via passageways 74. The liquid supply apparatus 75 is capable of supplying the immersion liquid to the supply ports 72 through the corresponding passageway 74. The recovery port 73 is capable of recovering the immersion liquid from the space 11. The recovery port 73 is connected to a liquid recovery apparatus 80 via a passageway 79. The liquid recovery apparatus 80 recovers the immersion liquid recovered via the recovery port 73 through the passageway 29. The porous member 33 is disposed in the recovery port 73. Performing the liquid supply operation using the supply ports 72 and the liquid recovery operation using the porous member 33 forms the space 11 between the projection system PS and the fluid handling structure IH on one side and the substrate W on the other side.

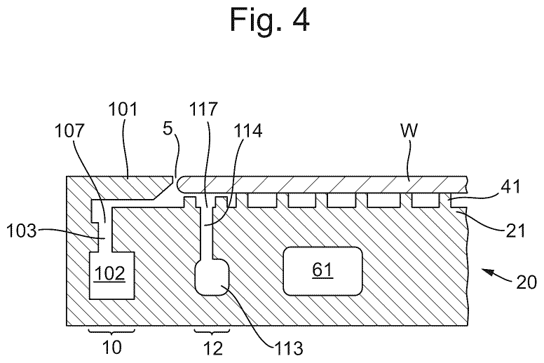

FIG. 4 illustrates part of a lithographic apparatus that is not in accordance with the present invention, but is useful for demonstrating features of the present invention. The arrangement illustrated in FIG. 4 and described below may be applied to the lithographic apparatus described above and illustrated in FIG. 1. FIG. 4 is a cross-section through a substrate support 20 and a substrate W. In an embodiment, the substrate support 20 comprises one or more conditioning channels 61 of a thermal conditioner 60, which is described in more detail below. A gap 5 exists between an edge of the substrate W and an edge of the substrate support 20. When the edge of the substrate W is being imaged or at other times such as when the substrate W first moves under the projection system PS (as described above), the immersion space 11 filled with liquid by the fluid handling structure IH (for example) will pass at least partly over the gap 5 between the edge of the substrate W and the edge of the substrate support 20. This can result in liquid from the immersion space 11 entering the gap 5.

The substrate W is held by a support body 21 (e.g. a pimple or burl table) comprising one or more burls 41 (i.e., projections from the surface). The support body 21 is an example of an object holder. Another example of an object holder is a mask holder. An under-pressure applied between the substrate W and the substrate support 20 helps ensure that the substrate W is held firmly in place. However, if immersion liquid gets between the substrate W and the support body 21 this can lead to difficulties, particularly when unloading the substrate W.

In order to deal with the immersion liquid entering that gap 5 at least one drain 10, 12 is provided at the edge of the substrate W to remove immersion liquid which enters the gap 5. In the embodiment of FIG. 4 two drains 10, 12 are illustrated though there may only be one drain or there could be more than two drains. In an embodiment, each of the drains 10, 12 is annular so that the whole periphery of the substrate W is surrounded.

A primary function of the first drain 10 (which is radially outward of the edge of the substrate W/support body 21) is to help prevent bubbles of gas from entering the immersion space 11 where the liquid of the fluid handling structure IH is present. Such bubbles may deleteriously affect the imaging of the substrate W. The first drain 10 is present to help avoid gas in the gap 5 escaping into the immersion space 11 in the fluid handling structure IH. If gas does escape into the immersion space 11, this can lead to a bubble which floats within the immersion space 11. Such a bubble, if in the path of the projection beam, may lead to an imaging error. The first drain 10 is configured to remove gas from the gap 5 between the edge of the substrate W and the edge of the recess in the substrate support 20 in which the substrate W is placed. The edge of the recess in the substrate support 20 may be defined by a cover ring 101 which is optionally separate from the support body 21 of the substrate support 20. The cover ring 101 may be shaped, in plan, as a ring and surrounds the outer edge of the substrate W. The first drain 10 extracts mostly gas and only a small amount of immersion liquid.

The second drain 12 (which is radially inward of the edge of the substrate W/support body 21) is provided to help prevent liquid which finds its way from the gap 5 to underneath the substrate W from preventing efficient release of the substrate W from the substrate table WT after imaging. The provision of the second drain 12 reduces or eliminates any problems which may occur due to liquid finding its way underneath the substrate W.

As depicted in FIG. 4, in an embodiment the lithographic apparatus comprises a first extraction channel 102 for the passage therethrough of a two phase flow. The first extraction channel 102 is formed within a block. The first and second drains 10, 12 are each provided with a respective opening 107, 117 and a respective extraction channel 102, 113. The extraction channel 102, 113 is in fluid communication with the respective opening 107, 117 through a respective passageway 103, 114.

As depicted in FIG. 4, the cover ring 101 has an upper surface. The upper surface extends circumferentially around the substrate W on the support body 21. In use of the lithographic apparatus, the fluid handling structure IH moves relative to the substrate support 20. During this relative movement, the fluid handling structure IH moves across the gap 5 between the cover ring 101 and the substrate W. In an embodiment the relative movement is caused by the substrate support 20 moving under the fluid handling structure IH. In an alternative embodiment the relative movement is caused by the fluid handling structure IH moving over the substrate support 20. In a further alternative embodiment the relative movement is provided by movement of both the substrate support 20 under the fluid handling structure IH and movement of the fluid handling structure IH over the substrate support 20. In the following description, movements of the fluid handling structure IH will be used to mean the relative movement of the fluid handling structure IH relative to the substrate support 20.

### Comparative Example

Substrate W warpage due to the stacking of film layers often means that the substrate W takes the form of an “umbrella” shape, where the centre of the substrate W is the highest point (i.e. furthest away from the substrate support WT), and radially outward of the centre, the substrate W curves downward. To mitigate umbrella-type deformation during loading, gas can be blown from the substrate support WT onto the underside of the substrate W in an edge region. This deforms the edge region of the substrate W upwards, mitigating any umbrella-shaped deformation, and ensuring that the radially outermost ring of burls 41 is the last point of contact between the substrate W and the substrate support WT during substrate loading. Consequently, the variability of friction at the outer circumferential ring of burls 41, which causes high substrate load reproducibility, is reduced. This “edge lift” technique could also be used with substrates W that are not in the form of an umbrella shape. For example, flat substrates W, bowl-shaped substrates W, and saddle-shaped substrates W could utilize this technique during substrate unloading.

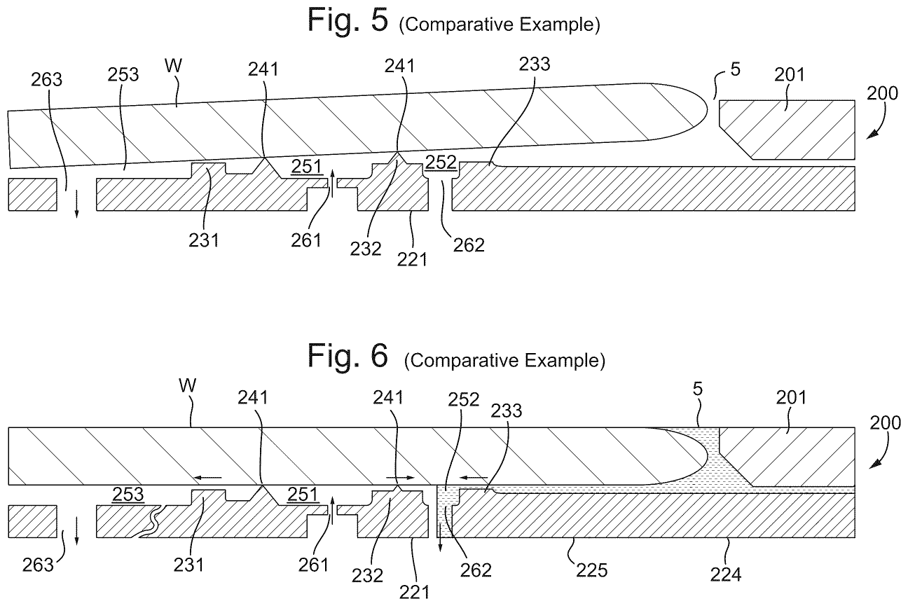

An example of a substrate support WT that implements this “edge lift” functionality is described below. This example is useful for highlighting aspects of the present invention. FIG. 5 and FIG. 6 show a portion of a substrate support 200. The portion of the substrate support 200 shown may be integrated within a configuration such as the substrate support 20 shown in FIG. 4. However, the portion of the substrate support 200 could also be integrated within other configurations of substrate support.

The substrate support 200 includes a support body 221. The support body 221 comprises a plurality of burls 241. When the substrate W is supported by the support body 221, the substrate W comes into direct contact with the support body 221. The support body 221 is the part of the substrate support 200 that physically supports the underside of the substrate W. The distal ends of the burls 241 form a plane at which the underside of the substrate W is supported. The underside of the substrate W comes into contact with the distal ends of the burls 241. The burls 241 are at the upper side of the support body 221.

As shown in FIGS. 5 and 6, the substrate support 200 further comprises a plurality of seals 231, 232, 233. The seals 231, 232, 233 are circumferential rings protruding from the substrate support 200. In this example, there are at least three seals: an inner seal 231, a middle seal 232 radially outwards of the inner seal 231; and an outer seal 233 radially outwards of the middle seal 232.

The plurality of seals 231, 232, 233 define a plurality of regions 251, 252, between the substrate support 200 and the substrate W. A multi-functional gutter 251 is a region extending circumferentially around the substrate support 200 between the inner seal 231 and the middle seal 232. A fluid extraction gutter 252 is a region extending circumferentially around the substrate support 200 between the middle seal 232 and the outer seal 233.

As shown in FIGS. 5 and 6, the substrate support 200 further comprises a plurality of openings 261, 262. In an embodiment, the support body 221 comprises a multi-functional opening 261 between the inner seal 231 and the middle seal 232 (in the multi-functional gutter 251), and a fluid extraction opening 262 between the middle seal 232 and the outer seal 233 (in the fluid extraction gutter 252).

The multi-functional opening 261 may be configured to supply and extract gas to/from the multi-functional gutter 252, and the fluid extraction opening 262 may be configured to extract fluid from the fluid extraction gutter 252.

A region radially inward of the inner seal 231 is a clamp region 253. In an embodiment, the substrate support 200 may further comprise a clamp opening 263 radially inward of the inner seal 231 (in the clamp region 253) that is configured to extract gas from the clamp region 253. When a substrate W is loaded onto the substrate support 200, the substrate W is first received by the plurality of e-pins in their extended position (not shown). The e-pins are then retracted such that the substrate W is lowered towards the substrate support 200. When the underside of the substrate W comes into contact with the plurality of burls 241, the e-pins continue to retract such that the substrate W is no longer in contact with the e-pins, and the substrate W is fully supported by the plurality of burls 241.

In this “loading state” (FIG. 5), gas is supplied by the multi-functional opening 261 to the multi-functional gutter 251, such that the pressure within the multi-functional gutter 251 increases. Consequently, the pressure within the multi-functional gutter 251 becomes larger than the ambient pressure, and a force is applied to the underside of the substrate W in an upward direction (that is, in a direction away from the substrate support 200). This upward force deforms the edges of the substrate W upwards. This may be such that umbrella-shaped deformation is reduced or completely eliminated. The upward force may even the reverse the direction of substrate deformation, such that the edge of the substrate W curves upwards (i.e. forms a bowl shape).

Gas may be extracted by the clamp opening 263 from the clamp region 253 during the loading phase, such that an under-pressure (pressure that is less than the ambient pressure) is established in the clamp region 253, and a force is applied to the underside of the substrate W in a direction that is towards the substrate support 200, such that the substrate W is clamped to the substrate support 200.

The fluid extraction opening 262 may be closed during the loading phase. This means that the fluid extraction opening 262 does not extract fluid.

FIG. 6 depicts a subsequent “clamp state”. In the clamp state, immersion fluid that has flowed through the gap 5 between the substrate W and the cover ring 201 also passes through the outer seal 233 and is present in the fluid extraction gutter 252. It is this immersion fluid that is extracted by the fluid extraction opening 262. Further, in the clamp state, pressure is continued to be supplied through the multi-functional opening 261 to the multi-functional gutter 251 so that immersion fluid does not pass beyond the middle seal 232. The pressure supplied to the multi-functional gutter 251 during this clamp state may be ambient pressure.

In this clamp state, the multi-functional opening 261 continues to supply gas to the multi-functional gutter 251 in order to prevent immersion fluid passing beyond the middle seal 232.

This configuration suffers from a number of disadvantages. First, there is no possible arrangement that satisfies edge lifting requirements and flatness requirements. For the edge lift force to result in the required edge lift deformation, the distance between the inner seal 231 and middle seal 232 must be made large. However, to avoid the presence of a flatness bump during the clamp state, the distance between the inner seal 231 and the middle seal 232 must be made small. Unless otherwise specified, the distance between seals (or the distance between circumferential walls in the claims) refers to the distance between the opposing faces of the seals. For example, the distance between the inner seal 231 and the middle seal 232 is the distance between the radially outer surface of the inner seal 231 and the radially inner surface of the middle seal 232.

It is necessary for the air entering through the multi-functional opening 261 during the clamp state to be humidified. This is because, if the humidity is too low, an excessive cold load will be applied to the substrate support 200. For example, an excessive cold load will be applied in and around the fluid extraction region 252 and fluid extraction opening 262. This can cause transient structural deformation of the substrate support 200, which can eventually lead to overlay penalty. A second disadvantage of the above example is that, if the humidity of air entering the multi-functional opening 261 during the clamp state is too high, it is likely to move radially inwards to the clamp region 253. If a humidity gradient is present in the clamp region 253, electrochemical reactions occur on the burls 241, which lead to a flatness drift in the clamp region 253 of the substrate support 200. This means that, when the substrate support 200 supports a substrate W, there is a drift in the flatness of the substrate W.

Further, in the above example, uncontrolled air (e.g. air which contains contaminants, or air with an uncontrolled temperature) may flow between the substrate W and the substrate support 200.

### Embodiment

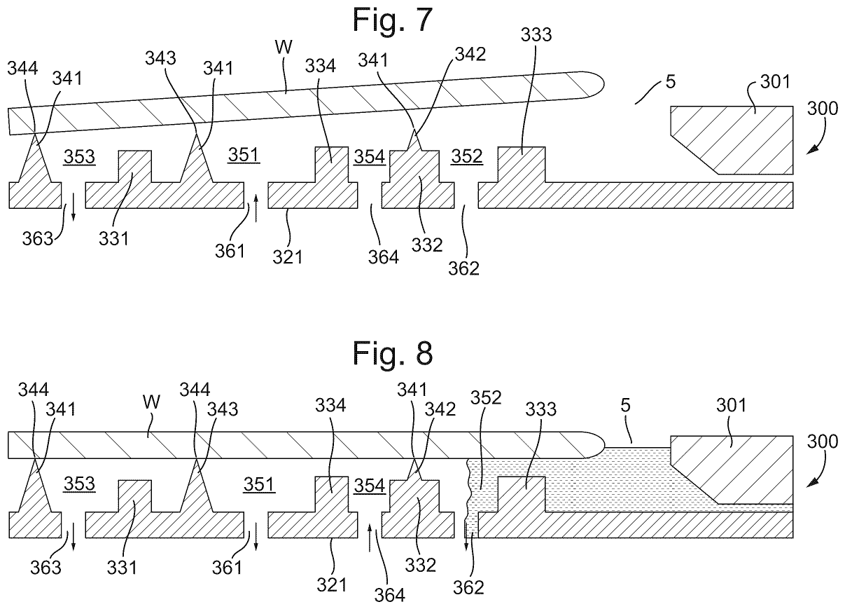

FIGS. 7 to 10 illustrate a portion of a substrate support 300 in accordance with the present invention. The substrate support 300 is similar to the substrate support 200 illustrated in the comparative example, but includes an additional seal (inner-middle seal 334) and an additional opening (ambient opening 364). As with the portion of the substrate support 200 in the above comparative example, the portion of the substrate support 300 could be integrated within a structure such as that of the substrate support 20 described above. However, the present invention is not limited to this, and the portion of the substrate support 300 could be integrated within substrate supports with different configurations.

As in the comparative example, the substrate support 300 includes a support body 321. The support body 321 comprises a plurality of burls 341. When the substrate W is supported by the substrate support 300, the substrate W comes into direct contact with the support body 321. The support body 321 is the part of the substrate support 300 that physically supports the underside of the substrate W. The distal ends of the burls 341 form a plane at which the underside of the substrate W is supported. The underside of the substrate W comes into contact with the distal ends of the burls 341. The burls 341 are at the upper side of the support body 321.

As shown in FIGS. 7 to 10, the substrate support 300 comprises a plurality of seals 331, 332, 333, 334. These seals 331, 332, 333, 334 are circumferential rings protruding from the substrate support 300. In an embodiment, there are at least four seals: an inner seal 331, an inner-middle seal 334 radially outwards of the inner seal 331; a middle seal 332 radially outwards of the inner-middle seal 334; and an outer seal 333 radially outwards of the middle seal 332. The inner seal 331 is an example of a first circumferential wall, the inner-middle seal 334 is an example of a second circumferential wall, the middle seal 332 is an example of a third circumferential wall, and the outer seal 333 is an example of a fourth circumferential wall. In the embodiments shown in FIGS. 7 to 10, the inner seal 331, the inner-middle seal 334, the middle seal 332, and the outer seal 333 are circumferential rings that protrude from the surface of the support body 321.

The plurality of seals 331, 332, 333, 334 define a plurality of regions between the substrate support 300 and the substrate W. A multi-functional gutter 351 is a region extending circumferentially around the substrate support 300 between the inner seal 331 and the inner-middle seal 334. An ambient gutter 354 is a region extending circumferentially around the substrate support 300 between the inner-middle seal 334 and the middle seal 332. A fluid extraction gutter 352 is a region extending circumferentially around the substrate support 300 between the middle seal 332 and the outer seal 333.

In FIGS. 7 to 10, the support body 321 further comprises a plurality of openings 361, 364, 362. These are: a multi-functional opening 361 arranged between the inner seal 331 and the inner-middle seal 334 (in the multi-functional gutter 351); an ambient opening 364 arranged between the inner-middle seal 334 and the middle seal 332 (in the ambient gutter 354); and a fluid extraction opening 362 arranged between the middle seal 332 and the outer seal 333 (in the fluid extraction gutter 352). The multi-functional opening 361 is an example of a first opening, the ambient opening 364 is an example of a second opening, and the fluid extraction opening 362 is an example of a third opening.

In an embodiment, the multi-functional opening 361 is configured to supply and extract gas to the multi-functional gutter 351. However, the multi-functional opening 361 may be configured to only supply gas. The ambient opening 364 may be configured to be in fluid communication with ambient pressure. The ambient pressure could be provided from the atmosphere, or from a fluid source within the system. The ambient opening 364 may also be configured to be in fluid communication with positive pressure (pressure that is greater than ambient pressure). The fluid extraction opening 362 is configured to extract fluid from the fluid extraction gutter 352. The fluid extraction opening 362 is an example of the second opening 117 in the substrate support 20 depicted in FIG. 4. As with the second opening 117 in the substrate support 20, the fluid extraction opening 362 may be part of a drain system, such as the second drain 12 in the substrate support 20, with a plurality of channels and passageways configured to contain fluid.

As in the comparative example, a region radially inward of the inner seal 331 is a clamp region 353. In an embodiment, the support body 321 may further comprise a clamp opening 363 radially inward of the inner seal 331 (in the clamp region 353) that is configured to extract gas from the clamp region 353.

As in the comparative example, when a substrate W is loaded onto a substrate support 300, the substrate W is first received by a plurality of e-pins in their extended position (not shown). The e-pins are then retracted such that the substrate W is lowered towards the substrate support 300. When the underside of the substrate W comes into contact with the plurality of burls 341, the e-pins continue to retract such that the substrate W is no longer in contact with the e-pins, and the substrate W is fully supported by the plurality of burls 341.

In this “loading state” (FIG. 7), gas is supplied by the multi-functional opening 361 to the multi-functional gutter 351, such that the pressure within the multi-functional gutter 351 increases. Consequently, the pressure within the multi-functional gutter 351 becomes larger than the ambient pressure. Because the pressure within the multi-functional gutter 351 is greater than the pressure above the substrate W, a force is applied to the substrate W in an upward direction (that is, in a direction away from the substrate support 300).

The substrate support 300 is configured such that the multi-functional gutter 351 is situated near to the edge of the substrate W. Consequently, the upward force applied to the substrate W is applied to an edge region of the substrate W. In a substrate W with a diameter of 300 mm, the edge region may be a region where the distance to the center of the substrate W (i.e. the radial distance) is greater than 135 mm. Generally, the edge region may be a region where the distance to the center of the substrate W is greater than 45% of the substrate W diameter. Applying the upward force in this region causes the edges of the substrate W to deform upwards. This ensures that, during substrate W loading, the radially outermost circumferential ring of burls 342 is the last point of contact between the substrate support 300 and the substrate W, which may not otherwise be the case when an “umbrella”-shaped substrate W is loaded onto the substrate support 300. This reduces the variability of friction between the radially outermost circumferential ring of burls 342 and the underside of the substrate W, which reduces the substrate W load reproducibility.

The ambient opening 364 and the fluid extraction opening 362 may be closed during the loading phase. This means that the ambient opening 364 is not in fluid communication with ambient pressure, and the fluid extraction opening 362 does not extract fluid.

In a method of the invention, gas is extracted from the clamp opening 363 during the loading phase, such that an under-pressure (pressure that is less than the ambient pressure) is established in the clamp region 353. Because the pressure within the clamp region 353 is lower than that above the substrate W, a force is applied to the substrate W towards the substrate support 300, such that the substrate W is clamped to the substrate support 300. This force is applied radially inwards of the multi-functional gutter 361. This means that the clamping force can be exerted at the same as the edge lift force is exerted.

At a certain point, the substrate support 300 transitions from the loading state to a “clamp state”. This clamp state is an example of a “normal state”. Preferably, the substrate support 300 transitions from the loading state to the clamp state in response to a measured value of pressure in the clamp region 353. Specifically, the substrate support 300 transitions from the loading state to the clamp state when a measured value of pressure within the clamp region 353 decreases below a predefined threshold value. However, the present invention is not limited to this, and the substrate support 300 may transition from the loading state to the clamp state in response to other measured values, or in response to a predetermined timing.

In the clamp state (FIG. 8), the multi-functional opening 361 may extract gas from the multi-functional gutter 351, such that an under-pressure is established within the multi-functional gutter 351. This means that, as in the clamp region 353, a clamping force is exerted on the portion of the underside of the substrate W corresponding to the multi-functional gutter 351. Alternatively, the multi-functional opening 361 may be closed, such that it is not in fluid communication with any of ambient pressure, over-pressure, or under-pressure.

In the clamp state, the ambient opening 364 and the fluid extraction opening 362 are open. That is, the ambient opening 364 is in fluid communication with ambient pressure and the fluid extraction opening 362 extracts fluid from the fluid extraction gutter 352. Alternatively, the ambient opening 364 may be in fluid communication with a positive pressure source. FIG. 8 shows that, when the substrate W is in the clamp state, immersion fluid that has flowed through the gap 5 between the substrate W and the cover ring 301 also passes between the outer seal 333 and the underside of the substrate W, and is present in the fluid extraction gutter 352. It is this immersion fluid that is extracted by the fluid extraction opening 362. The extraction pressure of the fluid extraction opening 362, the middle seal 332, and the ambient pressure within the ambient gutter 354 prevent the immersion fluid flowing radially inward of the middle seal 332.

It is important that immersion fluid does not flow inward to reach the multi-functional gutter 351 or the multi-functional opening 361, because when the multi-functional opening 361 supplies gas, immersion fluid would be blown towards critical surfaces, such as a grid plate, sensors (Transmission Image Sensor (TIS), Integrated Lens Interferometer At Scanner (ILLIAS), Parallel ILLIAS (PARIS)), and the top sides of the substrate W. This can result in significant system performance issues, such as Stage Positioning Measurement (SPM) error and substrate defectivity. In the present invention, there are two seals (the middle seal 332 and the inner-middle seal 334) between the multi-functional gutter 351 and the immersion fluid when the substrate support 300 is in the clamp state. This means that the immersion fluid is much less likely to reach the multi-functional gutter 351 compared to in the comparative example, in which there is only one seal (the middle seal 232) between the immersion fluid and the multi-functional gutter 251.

In the clamp state, the clamp opening 363 may continue to extract gas, such that the magnitude of the difference in pressure between the clamp region 353 and the area above the substrate W increases. Alternatively, the clamp opening 363 may be closed, and the magnitude of the pressure within the clamp region 353 may remain substantially constant. As a further alternative, gas may be periodically extracted through the clamp opening 363 such that the magnitude of the pressure within the clamp region 353 remains substantially constant.

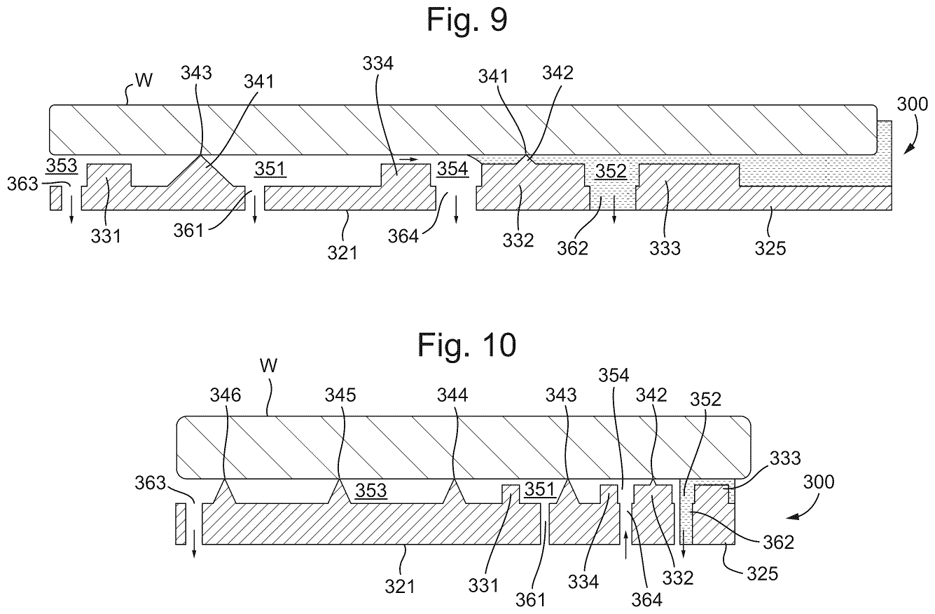

The substrate support 300 may also be configured to operate in a “bypass state” (see FIG. 9), which is an alternative to the clamp state. In the bypass state, the clamp opening 363 and the multi-functional opening fluid extraction opening 362 operate as in the clamp state. However, the ambient opening 364 may be closed. This means that the ambient opening 364, and therefore the ambient gutter 354 are not in fluid communication with ambient pressure. Alternatively, the ambient opening 364 may remain open, but in fluid communication with a pressure source that is not sufficient to prevent immersion fluid travelling radially inward beyond the middle seal 332. Consequently the immersion fluid surrounds the middle seal 332 and the outer circumferential ring of burls 342. In this bypass state, the multi-functional opening 361 supplies ambient or positive pressure to the multi-functional gutter 351 to prevent the immersion fluid travelling radially inward beyond the inner-middle seal 334 towards the clamp region 353. This scenario, in which the outer circumferential ring of burls 342 is “wet” may be preferable in some cases, because having a “wet” outer circumferential ring of burls 342 affects the friction between the distal ends of the burls 342 and the underside of the substrate W.

In an embodiment, the following operations are performed to unload the substrate W from the substrate support 300. First, the immersion liquid around the substrate W is removed. How the immersion liquid is removed is not particularly limited. It may be performed by channels 13 in the fluid handling structure IH, as shown in FIG. 2, or by the porous member 33 in the fluid handling structure IH, as shown in FIG. 3. The multi-functional opening 361 is then switched to supply gas to the multi-functional gutter 351 such that the pressure within the multi-functional gutter 351 increases, as in the loading phase. Consequently, the pressure within the multi-functional gutter 351 becomes larger than the ambient pressure. Because the pressure within the multi-functional gutter 351 is greater than the pressure above the substrate W, a force is applied to the underside of the substrate W in an upward direction (that is, in a direction away from the substrate support 300).

Next, the clamp opening 363 is closed. As a result, the pressure within the clamp region 353 gradually increases towards the ambient pressure, such that the clamping force exerted on the substrate W diminishes. To remove the substrate W from the substrate support 300, the e-pins (not shown) are extended from their retracted position. As the e-pins are extended, their distal portions come into contact with the underside of the substrate W. As the e-pins continue to extend, the substrate W is lifted off the plurality of burls 341, 342.

In an embodiment, when the substrate W is supported by the substrate support 300, top surfaces of the plurality of seals 331, 332, 333, 334 (that is, surfaces of the plurality of seals 331, 332, 333, 334 that are substantially parallel with and closest to the substrate W) do not contact the underside of the substrate W. However, the distances between the top surfaces of the plurality of seals 331, 332, 333, 334 and the underside of the substrate W are such that at least a partial seal is formed between the top surfaces of the seals 331, 332, 333, 334 and the underside of the substrate W. That is, the plurality of seals 331, 332, 333, 334 inhibit, but do not fully prevent, the flow of fluid between the plurality of gutters 351, 352, 354 and the clamp region 353.

The distance between the top surfaces of the seals 331, 332, 333, 334 and the underside of the substrate W is preferably smaller than 10 μm and further preferably smaller than 5 μm, and preferably larger than 1 μm and further preferably larger than 3 μm.

In an embodiment, the distance between the top surface of a seal 331, 332, 333, 334 and the underside of the substrate W may not be the same for each seal 331, 332, 333, 334. For instance, the distance between the top surface of a seal and the underside of the substrate W may be smaller for the seals that define the multi-functional gutter 351 (i.e., the inner seal 331 and inner-middle seal 334). This is to restrict the flow of fluid from the multi-functional gutter 351 to other regions, which enables a higher pressure to be established in the multi-functional gutter 351 to provide the edge lift function. Further, restricting the flow past the inner seal 331 and the inner-middle seal 334 is beneficial in isolating the multi-functional gutter 351 and clamp region 353 from the ambient gutter 354. To optimize the substrate support 300 for the clamp state, the distance between the top surface of the outer seal 333 and the underside of the substrate W may be smaller than the distance between the top surface of the middle seal 332 and the underside of the substrate W. To optimize the substrate support 300 for the bypass state, the distance between a top surface of the middle seal 332 and the underside of the substrate W may be made smaller. This is to increase the capillary force on the immersion fluid in the gap between the middle seal 332 and the substrate W, ensuring that the middle seal 332 is surrounded by the immersion fluid, and the burl 342 is “wet”.

In the present invention, the edge lift force is exerted on the underside of the substrate W in the region corresponding to the multi-functional gutter 351 between the inner seal 331 and the inner-middle seal 334. During the clamp state, the atmospheric pressure or overpressure needed to prevent the immersion fluid flowing radially inward of the middle seal 332 is supplied by the ambient opening 364. Between the multi-functional opening 361 and the ambient opening 364 is the inner-middle seal 334. This means that the magnitude of the edge lifting force is dependent on the distance between the inner seal 331 and the inner-middle seal 334, and the size of the flatness bump is dependent on the distance between the inner-middle seal 334 and the middle seal 332. Consequently, the distance between the inner seal 331 and the inner-middle seal 334 (i.e. the size of the multi-functional gutter 351) can be made large enough to provide sufficient edge lifting force in the loading state.

Separately, the distance between the inner-middle seal 334 and the middle seal 332 can be made small enough to minimize the flatness bump in the substrate W when the substrate support 300 is in the clamp state. This is different to the comparative example, in which the multi-functional opening 261 provides the ambient pressure or over-pressure required to prevent the immersion fluid flowing radially inward of the middle seal 232. This means that, in the present invention, the problem exhibited in the comparative example whereby the distance between the inner seal 231 and the middle seal 232 cannot satisfy the edge lift force requirements and the flatness requirements is avoided.

Considering this, in an embodiment, the distance between the inner seal 331 and the inner-middle seal 334 is larger than the distance between the inner-middle seal 334 and the middle seal 332, and the distance between the middle seal 332 and the outer seal 333. For a substrate support 300 configured to support a substrate W with a diameter of 300 mm, the following dimensions are preferable. The radial distance between the inner seal 331 and the inner-middle seal 334 should be greater than 0.5 mm, preferably greater than 1 mm, and preferably greater than 1.5 mm. This is to ensure that the edge lift force exerted on the underside of the substrate W in the area corresponding to the multi-functional gutter 351 is sufficient to deform the edges of the substrate W such that it can be ensured that the outer circumferential ring of burls 342 is the last point of contact with the underside of the substrate W when the substrate support 300 is in the loading state. Preferably, the distance between the inner seal 331 and the inner-middle seal 334 is less than 10 mm.

The distance between the inner-middle seal 334 and the middle seal 332, the distance between the middle seal 332 and the outer seal 333, and the distance between the outer seal 333 and the circumferential edge of the substrate W should be small enough for the multi-functional gutter to be sufficiently close to the edge of the substrate W. In this context, “sufficiently close” means close enough for the edge lift force exerted on the underside of the substrate W in the region corresponding to the multi-functional gutter 351 to be such that the edge region of the substrate W is deformed upwards, and it can be ensured that the outer circumferential ring of burls 342 is the last point of contact with the underside of the substrate W when the substrate support 300 is in the loading state.

Preferably, the distance between the inner-middle seal 334 and the middle seal 332 is less than 1 mm, further preferably less than 0.8 mm and further preferably less than 0.6 mm. Preferably, the distance between the inner-middle seal 334 and the middle seal 332 is greater than 0.2 mm. As discussed above, this distance is to ensure that the multi-functional gutter 351 is located sufficiently close to the circumferential edge of the substrate W, and also to minimise the flatness bump in the substrate W between the inner-middle seal 334 and the middle seal 332 when the substrate W is clamped to the substrate support 300.

The distance between the centre of the middle seal 332 in a radial direction and the centre of the outer seal 333 in a radial direction may be approximately half of the burl pitch (the distance between the plurality of burls 341). That is, the distance between the centre of the middle seal 332 in a radial direction and the centre of the outer seal 333 in a radial direction is preferably greater than 30% of the burl pitch, further preferably greater than 40% of the burl pitch, and further preferably greater than 45% of the burl pitch. The distance between the centre of the middle seal 332 in a radial direction and the centre of the outer seal 333 in a radial direction is preferably less than 70% of the burl pitch, further preferably less than 60% of the burl pitch, and further preferably less than 55% of the burl pitch. For example, in the case that the burl pitch is 1.5 mm, the distance between the centre of the middle seal 332 in a radial direction and the centre of the outer seal 333 in a radial direction is preferably greater than 0.45 mm, further preferably greater than 0.6 mm, and further preferably greater than 0.68 mm. In this case, the distance between the centre of the middle seal 332 in a radial direction and the centre of the outer seal 333 in a radial direction is preferably less than 1.05 mm, further preferably less than 0.9 mm, and further preferably less than 0.83 mm. As stated above, the distance between the centre of the middle seal 332 in a radial direction and the centre of the outer seal 333 in a radial direction is small to ensure that the multi-functional gutter 351 is sufficiently close to the edge of the substrate W. In addition, the range specified above ensures that the bending moments acting on the substrate W are balanced, thus ensuring optimal flatness of the substrate W.

Further, the distance between the outer seal 333 and the circumferential edge of the substrate W is preferably less than 5 mm, further preferably less than 3 mm, and further preferably less than 2.5 mm. The distance between the outer seal 333 and the circumferential edge of the substrate W is preferably greater than 1 mm. Again, as discussed above, this distance is small to ensure that the multi-functional gutter 351 is located sufficiently close to the circumferential edge of the substrate W.

For substrates W that do not have a diameter of 300 mm, the dimensions should be scaled in accordance with the diameter of the substrate W. Generally, the distance between the inner seal 331 and the inner-middle seal 334 should be greater than 0.15% of the diameter of the substrate W, preferably greater than 0.3% of the diameter of the substrate W, and further preferably greater than 0.5% of the diameter of the substrate W, and less than 3.3% of the diameter of the substrate W. The distance between the inner-middle seal 334 and the middle seal 332 should be less than 0.5% of the diameter of the substrate W, preferably less than 0.25% of the diameter of the substrate W and further preferably less than 0.2% of the diameter of the substrate W, and should be greater than 0.05% of the diameter of the substrate W. Further, the distance between the outer seal 333 and the edge of the substrate W is preferably less than 1.7% of the diameter of the substrate W, further preferably less than 1% of the diameter of the substrate W, and further preferably less than 0.8% of the diameter of the substrate W. The distance between the outer seal 333 and the circumferential edge of the substrate W is preferably greater than 0.3% of the diameter of the substrate W.

It is noted that the ranges quoted above for the distance between the radial centre of the middle seal 332 and the radial centre of the outer seal 333 are not limited to being advantageous in the above embodiment. For example, the range could be implemented in the substrate support 200 of the comparative example to produce the same technical effect (the balancing of bending moments to ensure the flatness of the substrate W).

The width of each of the plurality of seals 331, 332, 333, 334 (that is, the distance in the radial direction between the seal's inner circumferential edge and the seal's outer circumferential edge) is preferably greater than 0.1 mm, and further preferably greater than 0.2 mm. The width of each of the plurality of seals 331, 332, 333, 334 is preferably less than 1 mm and further preferably less than 0.6 mm

The width of each of the plurality of seals 331, 332, 333, 334 may not be the same. The width of some seals may be made larger in order to ensure that a ring of burls 342 can be situated on the top surface of the seal 332. In an embodiment, the widths of the middle seal 332 and the outer 333 are greater than the width of the inner seal 331 and the inner-middle seal 334. Preferably, the widths of the middle seal 332 and the outer seal are greater than 0.4 mm and less than 0.6 mm, such as 0.5 mm. The widths of the inner seal 331 and inner-middle seal 334 are preferably less than 0.3 mm and greater than 0.2 mm, such as 0.25 mm.

In an embodiment, the plurality of burls 341 are arranged in circumferential rings. A radially outermost circumferential ring of burls 342 may be situated on or around the middle seal 332. This is because, when the substrate support 300 supports a substrate W, it is preferable for the outer circumferential ring of burls 342 to remain dry, i.e. not to come into contact with the immersion fluid. This is to prevent wear to the outer circumferential ring of burl 342, and to reduce the risk of edge roll-off (ERO).

In an embodiment, when a substrate W with a diameter of 300 mm is clamped onto the substrate support 300, the radially outermost circumferential ring of burls 342 are preferably less than 10 mm from the circumferential edge of the substrate W, further preferably less than 5 mm from the circumferential edge of the substrate W, further preferably less than 4 mm from the circumferential edge of the substrate W, and further preferably less than 3.5 mm from the circumferential edge of the substrate W. When the substrate W with a diameter of 300 mm is clamped onto the substrate support 300, the radially outermost circumferential ring of burls 342 are preferably more than 1 mm away from the circumferential edge of the substrate W.

The diameter of each of the burls 341, 342 may not be the same. For example, each circumferential ring of burls 342-346 may have a different diameter. The diameter of burls 342-346 in a circumferential ring may depend on the radial distance from the centre of the substrate support 300. This is because the stiffness of a burl is proportional to its diameter. Consequently, by changing the diameter of the burls 341, 342, the amount of deformation at the burl-substrate interface can be adjusted. This means that the diameter of the burls 341, 342 can be controlled to ensure that the substrate W remains within required the required flatness tolerance, despite the complex pressure profile on the underside of the substrate W. The required diameter for each ring of burls 342-346 may be determined by optimization through experimentation or simulation.

FIG. 10 shows the outer five circumferential burls 342-346. In an embodiment, the burls 342 in a radially outermost circumferential ring have a larger diameter than the burls 341 in other circumferential rings. In another embodiment, the radially outermost circumferential ring of burls 342, third radially outermost circumferential ring of burls 344, and the fourth radially outermost circumferential ring 345 have a larger diameter than the burls in other circumferential rings 343, 346. Preferably, the diameter of the burls in the radially outermost circumferential ring 342, third radially outermost circumferential ring 344, and the fourth radially outermost circumferential ring 345 is between 200 μm and 350 μm, and the diameter of the burls in the other rings 343, 346 is between 150 μm and 250 μm. Further preferably, the diameter of the burls in the radially outermost circumferential ring 342, third radially outermost circumferential ring 344, and the fourth radially outermost circumferential ring 345 is between 250 μm and 330 μm, and the diameter of the burls in other circumferential rings 343, 346 is between 190 μm and 240 μm, Further preferably, the diameter of the burls in the radially outermost circumferential ring 342, the third radially outermost circumferential ring 344, and the fourth radially outermost circumferential ring 345 is between 260 μm and 280 μm, such as 270 μm, and the diameter of burls in other rings 343, 346 is between 200 μm and 220 μm, such as 210 μm.

Depending on the configuration of the substrate support 300, it may be the proportions of the diameter of burls 341 relative to other burls 341 which is important for ensuring flatness of the substrate W. Considering this, in an embodiment, the diameter of burls in the radially outermost circumferential ring 342, third radially outermost circumferential ring 344, and fourth radially outermost circumferential ring 345 is more than 10% larger than the diameter of burls in other rings 343, 346, preferably more than 20% larger than the diameter of burls in other rings 343, 346 and further preferably more than 25% larger than the diameter of burls in other rings 343, 346. In the embodiment, the diameter of burls 342, 344, 345 is less than 100% larger than the diameter of burls in other rings 343, 346, preferably less than 50% of the diameter of burls in other rings 343, 346, and further preferably less than 30% of the diameter of burls in other rings 343, 346.

When adjusting the relative proportions of the diameters of burls 341, 342, it is preferable to increase the diameters of burls 341, 342, rather than decrease the diameters of burls 341, 342. This is because burls 341, 342 with a smaller diameter are likely to wear down faster, which would mean that the substrate support 300 (or the support body 321) would need to be replaced more regularly. To avoid the burls 341, 342 wearing down too quickly, the diameters of all of the burls 341, 342 should be greater than 150 μm.

Other techniques could be used to adjust the stiffness of the burls 341, 342, such as changing the material, or applying a coating, e.g., diamond and DLC. However, the substrate W typically has a lower stiffness than the burls 341, 342, so the deformation at the substrate-burl interface is not significantly affected by the burl material or coating. Consequently, these techniques are not particularly effective for controlling the flatness of the substrate W.

In the above embodiment, the burl pitch (the distance between burls 341, 342) is preferably greater than 0.5 mm, further preferably greater than 1 mm, and further preferably greater than 1.4 mm. The burl pitch is preferably less than 3 mm, further preferably less than 2 mm, and further preferably less than 1.6 mm, such as 1.5 mm.

Controlling the flatness of a substrate W on the substrate support 300 by adjusting burl diameters depending on their radial position is not limited to the arrangement of seals 331, 332, 333, 334 described in the present invention. The technique, and the dimensions given above, could be implemented in a wide range of substrate supports 300 with different arrangements of seals.

The burls 341 may have a height (that is, a dimension form the surface of the support body 321 to the burl's distal end) of approximately 150 μm. However, the burls 341 may be any suitable height.

The gas that is supplied through the openings 361, 362, 363, 364, for example, through the multi-functional opening 361 in the loading state and through the ambient opening 364 in the clamp state is not particularly limited. For example, clean-dry air (CDA), humidified air, or N₂ could be supplied. Preferably, humidified air is supplied, particularly through the ambient opening 364 in the loading state. This is because CDA with very low humidity can cause the evaporation of any immersion fluid on the outer seal 333, which creates a large cold load on the outer seal 333. This can cause transient structural deformation to the substrate support 300, which can lead to overlay penalty. Humidified air means that less immersion fluid is evaporated from the around the outer seal 333, and the cold load is reduced.

In the substrate support 200 in the comparative example as shown in FIGS. 5 and 6, supplying humidified air to the multi-functional opening 261 during the clamp state is not preferable, because of the risk of humidity moving radially inwards towards the clamp region 253, which can cause electrochemical reactions on the burls 341 in the clamp region 353, leading to a drift in the flatness of the substrate W. However, in the present invention, there are two seals (the inner seal 331 and the inner-middle seal 334) between the ambient opening 364 (which supplies humidified air in the clamp state) and the clamp region 353. This significantly suppresses any humidity entering through the ambient opening 364 from reaching the clamp region 353. The presence of these two seals 331, 334 between the ambient opening 364 and the clamp region 353 also minimizes the risk of uncontrolled air (air containing contaminants, and/or having an uncontrolled temperature) flowing between the substrate W and the substrate support 300.

In the above description, a single opening 361, 362, 363, 364 has been referred to in each of the gutter regions 351, 352, 354 and the clamp region 353. The openings 361, 362, 363, 364 could extend circumferentially all of the way around the substrate support 300. Alternatively, the openings 361, 362, 363, 364 may be a circular holes. Preferably, there are a plurality of hole-shaped openings distributed evenly around each region 351, 352, 353, 354. In the case that there are a plurality of hole-shaped openings within each region, each opening within a region could be configured in the same way (i.e. in the way as the opening already defined in the given region). For example, there may be a plurality of openings in the fluid extraction gutter 352, each of which is configured to extract fluid in the same way as the fluid extraction opening 362. However, the additional openings may be configured to operate in a different way to the opening already defined. For example, the fluid extraction gutter 352 could further include openings configured to supply fluid. The multi-functional opening 361 in the multi-functional gutter 351 is configured to supply and/or extract gas. In the case that there are multiple openings within the multi-functional gutter 351, each may be configured to both extract and supply gas. Alternatively, some openings may be configured only to supply gas, and others may be configured only to extract gas.

The multi-functional opening 361 is the restrictive feature within the fluid circuit. Therefore, the diameter of the multi-functional opening 361 may be smaller than the diameter of the ambient opening 364. Preferably, the diameter of the multi-functional opening 361 is between 100 μm and 200 μm. For the other openings 362, 363, 364, the diameter is not particularly limited. It is preferable that their diameters are large to allow fluid to flow freely through them and to minimize the risk of blockage. However, the diameters of these openings 362, 363, 364 must be small enough to fit between the seals.

The mechanism for opening and closing these openings 361, 362, 363, 364 is not particularly limited, and could utilise any standard valve or equivalent. Similarly, the systems for supplying and extracting gas to and from the openings 361, 362, 363, 364 (providing positive and negative pressure) are not particularly limited, and could involve any suitable standard components or methods.

### The Multi-Functional Channel

As explained above in relation to FIG. 4, openings 107, 117 on an upper surface of the substrate support WT may be connected to channels 102, 113 within the substrate support WT via passageways 103, 114. The channels 102, 113 may be cavities that extend circumferentially around the substrate support WT, allowing fluid to be transported between the openings 107, 117 in the substrate support WT and, for example, a fluid management system external to the substrate support WT. The passageways 103, 114 may be substantially vertical holes that extend upward from the channels 102, 113 to the openings 107, 117, facilitating fluid communication therebetween.

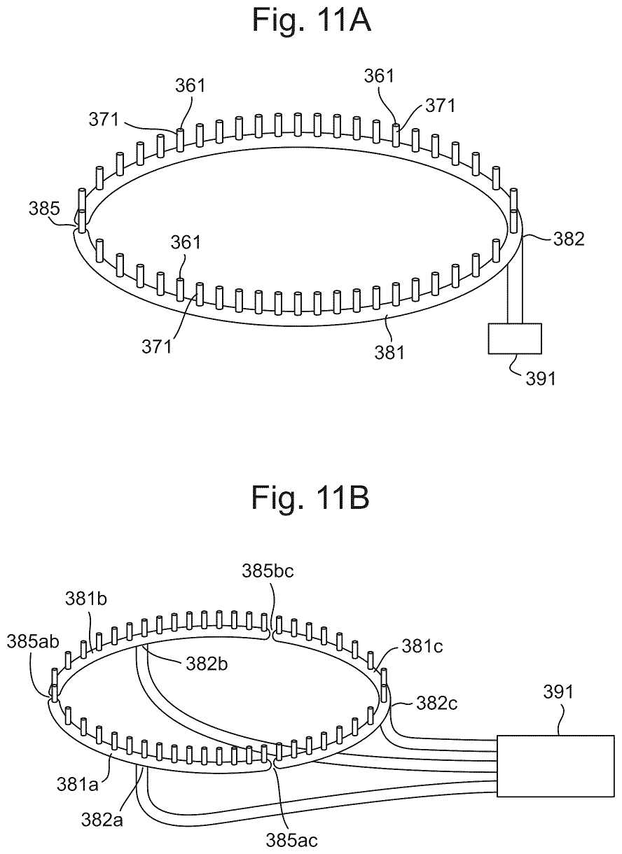

FIG. 11A depicts an example of a channel. The channel depicted may be a multi-functional channel 381. As shown in FIG. 11A, numerous multi-functional passageways 371 may extend vertically upwards from the multi-functional channel 381. Openings at ends of the multi-functional passageways 371 opposite to the multi-functional channel 381 may be the multi-functional openings 361. The multi-functional channel 381 may be connected to an external fluid management system 391 at a connection point 382. The fluid management system 391 may control the follow of fluids into and out of the multi-functional channel 381. The fluid management system 391 may include, for example, flow restrictors (not shown).

The multi-functional channel 381 may be circular, but not form a complete circle. This may be because there is a discontinuity 385 in the circle formed by the multi-functional channel 381. This may mean that fluid is not able to flow from the fluid management system 391 all the way around the multi-functional channel 381 without changing direction. The discontinuity 385 may be located at the opposite side of the multi-functional channel 381 to the connection point 382. That is, the discontinuity 385 in the multi-functional channel 381 and connection point 382 may be separated by approximately 180°.

To provide the edge lift force described above, gas may flow from the fluid management system 391 and into the multi-functional channel 381 via the connection point 382. After entering the multi-functional channel 381, the flow of gas may split, with approximately half of the flow of gas travelling rightward (i.e., anticlockwise as shown in FIG. 11A) and the other half of the flow of gas flowing leftward (i.e., clockwise as shown in FIG. 11A). As the flow of gas passes a multifunctional passageway 371, a portion of the flow of gas will flow up the multi-functional passageway 371. This portion of the flow of gas will then flow through the multi-functional opening 361 and into the multi-functional gutter 351, resulting in an increase in pressure within the multi-functional gutter 351. The leftward and rightward flows of gas may travel around the multi-functional channel 381 until reaching the discontinuity 385. In so doing, the leftward and rightward flows of gas may each travel halfway around the multi-functional channel 381, such that all of the multi-functional passageways 371 are supplied with gas. In this way, the edge lift force can be provided around the whole circumference of the substrate W.

To effectively provide the edge lift functionality, it is desirable for the flow-rate through each of the multi-functional passageways 371 to be substantially the same. If the flow rate is not the same in each of the multi-functional passageways 371, and particularly if the flow rate is larger for multi-functional passageways 371 in some regions than multi-functional passageways 371 in other regions, the provision of the edge lift force may cause the substrate W to be tilted during loading. To ensure that the flow rate is substantially the same in each of the multi-functional passageways 371, it is desirable for the flow-rate within the multi-functional channel 381 to be substantially uniform around its circumference.

The multi-functional channel 381 and the multi-functional passageways 371 may be small because of restrictive geometrical constraints within the body of the substrate support WT. The restrictive geometrical constraints exist because there are numerous features which must be accommodated within the body of the substrate support WT, such as channels corresponding to each of the different types of openings, cooling channels, heaters, etc.

Due to the small dimensions of the multi-functional channel 381, pressure losses may occur as the flow of gas flows from the fluid management system 391 to the multi-functional openings 361. That is, the pressure of the fluid within the multi-functional channel 381 may decrease as the distance from the connection point 382 increases. For example, there may be a pressure difference of approximately 0.01 to 0.05 bar (1 to 5 kPa) between the connection point 382 and portions of the multi-functional channel 381 adjacent to the discontinuity 385. This may mean that the edge lift force provided to a portion of the substrate W located near to the connection point 382 is greater than the edge lift force provided to a portion of the substrate W located near to the discontinuity 385. The provision of a non-uniform edge lift force may cause a non-zero resultant moment to be exerted on the substrate W, causing the substrate W to be tilted during loading.

Further, pressure differences within the multi-functional channel 381 may cause the substrate support WT to become deformed. Consequently, the flatness of substrate support WT, and any substrate W supported by the substrate support WT may decrease. This may cause defectivity in the pattern printed on the substrate W. Further, if the substrate support WT is formed of two or more layers laminated together, high pressure differences within the multi-functional channel 381 may cause the layers to become delaminated.

To improve the uniformity of the edge lift force around the circumference of the substrate W (despite varying pressure within the multifunctional channel 381), the multi-functional openings 361 may be small, so as to restrict the flow-rate therethrough. For example, the diameter of the multi-functional openings 361 may be approximately 0.15 mm. This means that there may be a high risk of clogging. Further, this means that the multi-functional openings 361 need to be manufactured with high accuracy (i.e., with low tolerances), because any deviation in their diameter may lead to a change in the flow rate therethrough when the edge lift force is provided. The requirement for the multi-functional openings 361 to be manufactured with low tolerances means that the manufacturing and cleaning processes may be complex. Further, if multi-functional openings 361 are manufactured inaccurately, or if multi-functional openings 361 become clogged, the resulting non-uniform edge lift force applied to the substrate W may cause the substrate W to become deformed.

FIG. 11B depicts an alternative arrangement for providing fluid to the multi-functional openings 361. In FIG. 11B, three multi-functional channels 381a, 381b, 381c are provided. Each of the multi-functional channels 381a, 381b, 381c may correspond to a portion of the circumference of the substrate support WT, such that the multi-functional channels 381a, 381b, 381c are able to provide fluid to the multi-functional passageways 371 around the entirety of the circumference of the substrate support WT. Each of the multi-functional channels 381a, 381b, 381c may be the same size. For instance, the three multi-functional channels 381a, 381b, 381c may each correspond to approximately 120° of the circumference of the substrate support WT. Between each of the multi-functional channels 381a, 381b, 381c, there may be a discontinuity 385ac, 385ab, 385bc. Each multi-functional channel 381a, 381b, 381c may be connected directly to the fluid management system 391. That is, each multi-functional channel 381a, 381b, 381c may be connected to the fluid management system 391 via its own connection means (e.g., pipe or tube). The connection points 382a, 382b, 382c of each of the multi-functional channels 381a, 381b, 381c may be located approximately in the middle of the multi-functional channels 381a, 381b, 381c.

By providing multiple multi-functional channels 381a, 381b, 381 as described above, tilting of the substrate W can be suppressed. This is because, even if the flow-rate is non-uniform within each multi-functional channel 381a, 381b, 381c, the tilting moments applied to the substrate W will cancel each other out, such that the resultant moment when the substrate W is flat is approximately zero.

Also, by providing multiple multi-functional channels 381a, 381b, 381c, the size (in the circumferential direction) of each multi-functional channel 381a, 381b, 381c can be made smaller compared to a configuration in which there is a single multi-functional channel 381. For example, in a configuration with three multi-functional channels 381a, 381b, 381c, the size (in the circumferential direction) of each multi-functional channel 381a, 381b, 381c may be a third of the size (in the circumferential direction) of a configuration in which there is a single multi-functional channel 381.

Also, by providing multiple multi-functional channels 381a, 381b, 381c, the flow-rate through each multi-functional channel 381a, 381b, 381c can be made smaller compared to a configuration in which there is a single multi-functional channel 381. For example, in a configuration with three multi-functional channels 381a, 381b, 381c, the flow-rate within each multi-functional channel 381a, 381b, 381c may be a third of the flow-rate within a multi-functional channel in a configuration in which there is only a single multi-functional channel 381.

A reduction in the flow-rate within the multi-functional channels 381a, 381b, 381c means that the magnitude of the reduction in the pressure of the fluid flowing through the multi-functional channels 381a, 381b, 381c is decreased. This means that pressure differences within the multi-functional channels 381a, 381b, 381c are smaller (compared to pressure differences within a multi-functional channel 381 in a configuration with only one multi-functional channel 381). This means that the occurrence of substrate support warpage and/or delamination of bonded layers can be reduced. This also means that multi-functional openings 361 with a larger diameter may be provided without the risk of decreasing the uniformity of the edge lift force provided to the underside of the substrate W. By being able to increase the diameter of the multi-functional openings 361, the likelihood of clogging is decreased, and manufacturing and cleaning processes can be made simpler.

The fluid management system 391 may comprise adjustable flow restrictors for each of the multi-functional channels 381a, 381b, 381c. The adjustable flow restrictors may be configured such that the flow-rate of fluid provided to each of the three multi-functional channels 381a, 381b, 381c can be individually adjusted. The adjustable flow restrictors may be electrical and/or mechanical. The exact configuration of the adjustable flow restrictors may not be particularly limited. Using the adjustable flow restrictors, it may be possible to calibrate the flow-rate provided to each of the multi-functional channels 381a, 381b, 381c to ensure that the edge lift force provided to each of the three portions of the substrate W corresponding to the three multi-functional channels 381a, 381b, 381c are the same. By doing this, it can further be ensured that the substrate W does not tilt during loading. The calibration process may take into consideration factors such as clogged multi-functional openings 361 and variations in multi-functional opening 361 size. Consequently, by providing multiple multi-functional channels 381a, 381b, 381c, it can be ensured that the substrate W does not tilt despite the presence of clogged multi-functional openings 361 and variations in multi-functional opening 361 sizes. This means that the operation of the multi-functional openings 361 is more robust, because manufacturing errors and clogging can be mitigated. This, in turn, means that manufacturing tolerances can be increased (i.e., relaxed), and the manufacturing processes can be made less complex.

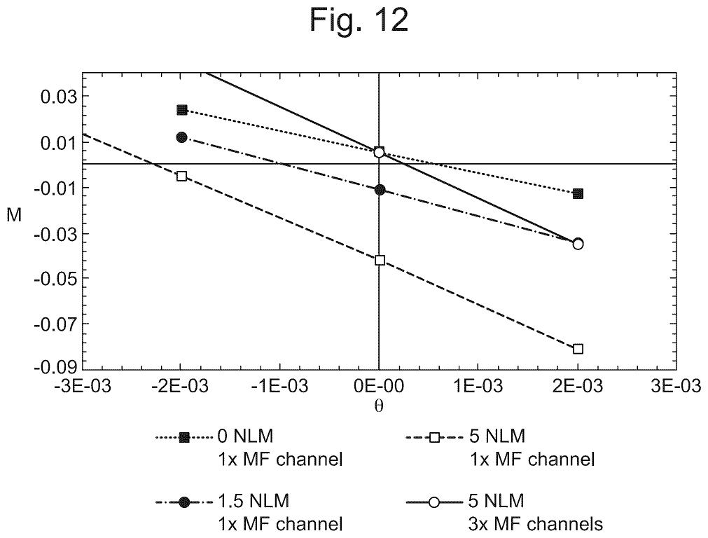

FIG. 12 depicts a plot of the moment about a horizontal axis (M) against tilt angle (θ) for a substrate support WT with a single multi-functional channel and a substrate support WT with three multi-functional channels 381a, 381b, 381c at several flow-rates. Specifically, the various dashed lines in FIG. 12 correspond to a substrate support WT with a single multi-functional channel 381 when the flow-rate within the multi-functional channel 381 is 0 NLM (normal litres per minute), 1.5 NLM and 5 NLM. The solid line in FIG. 12 corresponds to a substrate support WT with three multifunctional channels 381a, 381b, 381c when the sum of the flow-rates in the three multi-functional channels 381a, 381b, 381c is 5 NLM.

When a substrate W is loaded onto a substrate support WT, the tilt angle of the substrate W will be the angle of tilt which means that the resultant moment about a horizontal axis is zero. This angle of tilt may be referred to as the stable tilt angle. For the substrate support WT with a single multi-functional channel 381, as flow-rate increases, the magnitude of the stable tilt angle increases. When the flow-rate through the single multi-functional channel 381 is 0 NLM, the stable tilt angle may not be zero because of the effect of other openings within the substrate support WT, such as the clamp openings 363. The stable tilt angle at a flow-rate of 5 NLM may be a factor of 10 less for the substrate support WT with three multi-functional channels 381a, 381b, 381c than for the substrate support WT with a single multi-functional channel 381. The stable tilt angle for the substrate support WT with three multi-functional channels 381a, 381b, 381c at 5 NLM may not be zero. This may be because of the effects of other openings within the substrate support WT, such as the clamp openings 363.

Whilst the provision of multiple multi-functional channels has been described above with reference to a configuration with three multi-functional channels 381a, 381b, 381c, the technical effects described above may be achieved by providing a configuration in which the number of multi-functional channels is 2 or more. For example, the number of multi-functional channels may be 2, 3, 4, 5 or 10. Providing more multi-functional channels may mean that more control is gained over the tilting of the substrate W, and pressure differences within the multi-functional channels 381a, 381b, 381c can be further reduced. However, providing more multi-functional channels 381a, 381b, 381c may also make the substrate support WT more difficult to manufacture. By providing three multi-functional channels 381a, 381b, 381c, the above-described technical effects are realized without excessively complicating the manufacturing process.

Whilst the provision of multiple channels has been described above in relation to the multifunctional channel 381, the technique may also be implemented for other channels within the substrate support WT.

### General

The material of the substrate support 300 is not particularly limited, and could be any suitable material known in the art. Preferably, the substrate support 300 may be made out of silicon carbide (SiSiC).

Manufacture of the substrate support 300 may involve standard techniques known in the art. Some of the openings 361, 362, 363, 364 may be too small for methods such as electrical discharge machining (EDM). In this case, laser drilling may be utilized.

The present invention may provide a lithographic apparatus. The lithographic apparatus may have any/all of the other features or components of the lithographic apparatus as described above. For example, the lithographic apparatus may optionally comprise at least one or more of a source SO, an illumination system IL, a projection system PS, a substrate table WT, etc.

Specifically, the lithographic apparatus may comprise the projection system PS configured to project the radiation beam B towards the region of the surface of a substrate W. The lithographic apparatus may further comprise the substrate support 300 as described in any of the above embodiments and variations.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

Although specific reference may have been made above to the use of embodiments of the invention in the context of optical lithography, it will be appreciated that the invention, where the context allows, is not limited to optical lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A substrate support configured to support a substrate in a lithographic apparatus, the substrate support comprising:
a first circumferential wall;
a first opening radially outwards of the first circumferential wall and configured to supply and/or extract gas;
a second circumferential wall radially outwards of the first opening;
a second opening in fluid communication with ambient pressure and radially outwards of the second circumferential wall;
a third circumferential wall radially outwards of the second opening;
a third opening radially outwards of the third circumferential wall and configured to extract fluid; and
a fourth circumferential wall radially outwards of the third opening.

2. The substrate support according to claim 1, further comprising a fourth opening radially inwards of the first circumferential wall, configured to extract gas, and/or wherein the substrate support is configured such that the first, second, third, and fourth circumferential walls form at least a partial seal with a bottom surface of the substrate.

3. The substrate support according to claim 2, wherein the distance between the bottom surface of the substrate and the top surface of the third circumferential wall and the fourth circumferential wall is greater than that of the first circumferential wall and the second circumferential wall, and/or wherein the distance between the bottom surface of the substrate and the top surface of at least one of the first, second, third, and fourth circumferential walls is between 1 and 10 μm.

4. The substrate support according to claim 1, wherein the substrate support is configured such that when gas is supplied by the first opening, the pressure in a first region between the first circumferential wall and the second circumferential wall can be made greater than the ambient pressure around the substrate, and/or wherein the width of the third circumferential wall and the fourth circumferential wall is greater than that of the first circumferential wall and the second circumferential wall, and/or wherein the distance between the first circumferential wall and the second circumferential wall is larger than the distance between the second circumferential wall and the third circumferential wall and the distance between the third circumferential wall and the fourth circumferential wall, and/or wherein the distance between the second circumferential wall and the third circumferential wall is less than 0.5% of the diameter of the substrate and greater than 0.05% of the diameter of the substrate.

5. The substrate support according to claim 1, wherein the distance between the first circumferential wall and the second circumferential wall is greater than 0.5 mm, and/or wherein the distance between the second circumferential wall and the third circumferential wall is less than 1 mm, and/or wherein the distance between the first circumferential wall and the second circumferential wall is greater than 0.15% of the diameter of the substrate, and less than 3.3% of the diameter of the substrate, and/or wherein the distance between the centre of the third circumferential wall in a radial direction and the centre of the fourth circumferential wall in a radial direction is greater than 0.45 mm and less than 1.05 mm.

6. The substrate support according to claim 1, further comprising a plurality of burls arranged in a plurality of circumferential rings.

7. The substrate support according to claim 6, wherein diameters of the burls are dependent on their radial positions on the substrate support, and/or wherein a radially outermost circumferential ring of burls is situated on or around the third circumferential wall, and/or wherein the diameter of burls in the radially outermost circumferential ring, third radially outermost circumferential ring, and fourth radially outermost circumferential ring is larger than the diameter of burls in other rings.

8. The substrate support according to claim 6, wherein the diameter of burls in the radially outermost circumferential ring, third radially outermost circumferential ring, and fourth radially outermost circumferential ring is more than 10% larger than the diameter of burls in other rings and less than 100% larger than the diameter of burls in other rings, and/or wherein the diameter of burls in the radially outermost circumferential ring, third radially outermost circumferential ring, and fourth radially outermost circumferential ring is between 200 μm and 350 μm, and the diameter of burls in other rings is between 150 μm and 250 μm, and/or wherein the distance between the radial centre of the third circumferential wall and the radial centre of the fourth circumferential wall is greater than 30% of a burl pitch and less than 70% of the burl pitch.

9. The substrate support according to claim 1, wherein the diameter of the first opening is smaller than that of the second opening, and/or wherein the second opening is additionally in fluid communication with a positive pressure source.

10. The substrate support according to claim 9, wherein the second opening is configured to supply dry or humidified gas.

11. The substrate support according to claim 1, wherein the substrate support is made of SiSiC, and/or wherein there are a plurality of first openings distributed circumferentially around the substrate support, and/or wherein a first portion of multi-functional openings are in fluid communication with a first multi-functional channel and a second portion of multi-functional openings are in fluid communication with a second multi-functional channel.

12. The substrate support according to claim 1, wherein a first portion of multi-functional openings are in fluid communication with a first multi-functional channel, a second portion of multi-functional openings are in fluid communication with a second multi-functional channel, and a third portion of multi-functional openings are in fluid communication with a third multi-functional channel.

13. The substrate support according to claim 12, wherein the first multi-functional channel, the second multi-functional channel and the third multi-functional channel are cavities within the substrate support that extend around a portion of the substrate support in the circumferential direction, and/or wherein the first multi-functional channel, the second multi-functional channel and the third multi-functional channel are each directly connected to a fluid management system, such that flow-rates of gas supplied to each of the first multi-functional channel, the second multi-functional channel and the third multi-functional channel can be individually controlled.

14. A lithographic apparatus including the substrate support according to claim 1.

15. A method of loading a substrate onto a substrate support having a first circumferential wall, a second circumferential wall radially outward of the first circumferential wall, a third circumferential wall radially outward of the second circumferential wall, and a fourth circumferential wall radially outward of the third circumferential wall, with a first region between the first circumferential wall and the second circumferential wall, a second region between the second circumferential wall and the third circumferential wall, and a third region between the third and fourth circumferential wall, the method comprising:
supplying gas to the first region in a substrate loading step; and
extracting gas from the first region and fluid from the third region in a substrate clamping step.

16. The method according to claim 15, wherein the substrate support is configured such that the first, second, third, and fourth circumferential walls form at least a partial seal with a bottom surface of the substrate.

17. The method according to claim 15, wherein, when gas is supplied to the first region, the pressure in the first region can be made greater than the ambient pressure around the substrate.

18. The method according to claim 15, wherein the distance between the bottom surface of the substrate and the top surface of the third circumferential wall and the fourth circumferential wall is greater than that of the first circumferential wall and the second circumferential wall.

19. The method according to claim 15, wherein the width of the third circumferential wall and the fourth circumferential wall is greater than that of the first circumferential wall and the second circumferential wall.

20. The method according to claim 15, wherein the distance between the first circumferential wall and the second circumferential wall is larger than the distance between the second circumferential wall and the third circumferential wall and the distance between the third circumferential wall and the fourth circumferential wall.
